(19) United States
(12) Patent Application Publication
(10) Pub. No.: US 2014/0251403 A1
(43) Pub. Date: Sep. 11, 2014

(54) THERMOELECTRIC ENERGY CONVERTERS AND MANUFACTURING METHOD THEREOF

(71) Applicant: SHEETAK, INC., Austin, TX (US)

(72) Inventor: Uttam Ghoshal, Austin, TX (US)

(73) Assignee: SHEETAK, INC., Austin, TX (US)

(21) Appl. No.: 14/352,811

(22) PCT Filed: Oct. 17, 2012
(86) PCT No.: PCT/US12/60498

§ 371 Date: Apr. 18, 2014

Related U.S. Application Data
(60) Provisional application No. 61/627,931, filed on Oct. 20, 2011.

(51) Int. Cl. H01L 35/08; H01L 35/34

(52) U.S. Cl. CPC H01L 35/08; H01L 35/34
USPC 136/200; 427/123; 136/201

(57) ABSTRACT

The present disclosure provides a thermoelement with improved figure of merit for use in thermoelectric devices and a method of manufacturing the thermoelement. The thermoelement comprises metal layers, high power factor electrodes, a thermoelectric layer and a phonon blocking layer. The thickness of the thermoelectric layer is less than a thermalization length to achieve decoupling of phonons and electrons in the thermoelement. The phonon blocking layer reduces phonon conduction without significantly influencing electronic conduction. In an embodiment, the high power factor electrodes are made of materials with high Seebeck coefficient and high thermoelectric power factor that reduce thermal losses at interfaces of the thermoelement. The metal layers form outermost layers of the thermoelement and geometrically shaped to reduce heat flux in the thermoelement.

### BACKGROUND

The present disclosure relates to the field of thermoelectric devices. More specifically, the present disclosure relates to thermoelectric devices with improved figure of merit and Coefficient of Performance (COP).

It is known in the art that solid-state thermoelectric energy converters can be used for cooling as well as power generation applications. Use of the thermoelectric energy converters in cooling applications i.e., utilizing electrical energy to provide a cooling effect based on the Peltier effect is known in the art. Further, the solid-state thermoelectric energy converters can also be used to recover thermal energy and generate thermoelectric power i.e., to use a temperature gradient to generate electricity. This phenomenon relates to the Seebeck effect, and the corresponding thermoelectric energy converters form a functional part of thermoelectric power generation devices. The efficiency of the thermoelectric energy converters is determined by the figure-of-merit (ZT) according to the equation:

$$ZT = \frac{σ {S}^{2}}{λ} \qquad ( 1 )$$

where S is the thermopower, σ is the effective electrical conductivity, and λ is the effective thermal conductivity of the materials. The traditional thermoelectric energy converters have ZT<1 and COP<1 for temperature differentials ΔT=25K. Higher ZT values result in efficient thermoelectric energy converters with higher COP.

The solid-state thermoelectric energy converters can effectively replace conventional vapor compression systems in cooling applications and mechanical engines in power generation applications, provided the figure of merit exceeds three (ZT>3). Further, the thermoelectric energy converters provide zero Green House Gases (GHGs) emission, a significant advantage over the conventional vapor compression systems used in cooling applications.

Efforts have been made in the past to increase the figure of merit of the thermoelectric energy converters by using materials such as nanostructured bismuth telluride that have improved thermoelectric properties. Laboratory experiments with thermoelectric energy converters with such improved materials provide a figure of merit of about 1.2 at room temperature and COP of 1.5 at a temperature differential (ΔT) of 30K. However, these improvements in the figure of merit still do not make the thermoelectric energy converters competitive with the vapor compression systems in cooling applications and mechanical engines in power generation applications.

Further, thermoelectric energy converters may comprise one or more thermoelements. More specifically, thermoelements with thin films have been developed to achieve high figure of merit in the thermoelectric energy converters. Efforts made to improve thin film thermoelements include reduction of thermal conductivity in superlattice planes, transport and confinement in nanowires and quantum dots, optimization of ternary and quaternary chalcogenides, device level advancements like vacuum tunneling devices, thermionic emissions and non equilibrium transport. However, in spite of these attempts to increase the figure of merit of the thermoelectric energy converters, there has been no significant improvement in practical devices. There are no commercially available thermoelectric energy converters with ZT>1.

Thus, there exists a need for further contributions for development in the domain of thermoelectric energy converters.

### SUMMARY

The present invention provides a thermoelectric energy converter with improved figure of merit. An objective of the present disclosure is to provide a thermoelement of the thermoelectric energy converter with a high figure of merit for both cooling and power generation applications.

In an embodiment of the present disclosure, the thermoelement may be a Non-Equilibrium Asymmetric Thermoelectric (NEAT) device.

The thermoelement comprises a thermoelectric layer, a phonon blocking layer, high power factor electrodes (a first high power factor electrode and a second high power factor electrode), and metal layers. A first side of the thermoelectric layer is attached to the first side of the phonon blocking layer and a second side of the thermoelectric layer is attached to the second high power factor electrode. The second side of the phonon blocking layer is attached to the first high power factor electrode. The first and second high power factor electrodes are attached to metal layers (a first metal layer and a second metal layer). Further, the thermoelectric layer has a thickness less than a thermalization length. The thermalization length is a characteristic length below which electron transport and phonon transport are decoupled.

The phonon blocking layer is configured to block transportation of phonons, while allowing transportation of electrons. Thus, the phonon blocking layer reduces phonon conductivity without significantly affecting electronic conductivity. Thus, the total thermal conductivity, which is a sum of phonon conductivity and electronic conductivity, is reduced.

In an embodiment of the present disclosure, the thermoelement comprises one or more graded thermoelectric layers, a plurality of phonon blocking layers, a plurality of high power factor electrodes, and a plurality of metal layers. More specifically, the one or more graded thermoelectric layers have a thickness less than a thermalization length. The one or more phonon blocking layers are in contact with the one or more thermoelectric layers, wherein the one or more phonon blocking layers are configured to selectively block phonon conduction across the thermoelement and permit electron transport across the thermoelement. The plurality of high power factor electrodes are in contact with the one or more phonon blocking layers, wherein the plurality of high power factor electrodes are configured to reduce losses in the thermoelement. The plurality of metal layers are attached to the plurality of high power factor electrodes, wherein the plurality of metal layers are configured for constricted contacts of the thermoelement so as to reduce the heat flux across the thermoelement. In another embodiment of the present disclosure the plurality of metal layers are configured for multilayer consolidation of the thermoelement.

In an embodiment of the present disclosure, a method for manufacturing a thermoelement is disclosed. The method begins with deposition of the high power factor electrode on metal layers made of at least one of materials such as Al, Ni, W, Ta, or Mo using a Physical Vapor Deposition method. Thereafter, a phonon blocking layer is deposited on the high power factor electrode. In an embodiment of the present disclosure, an atomic layer of graphene or tunneling oxides such as Al₂O₃ is deposited as the phonon blocking layer using Chemical Vapor Deposition. In another embodiment, liquid metals are deposited using Physical Vapor Deposition as the phonon blocking layer. Thereafter, a thermoelectric layer is then deposited on the phonon blocking layer by a Physical Vapor Deposition method. Further, the thermoelectric layer is also annealed on the phonon blocking layer to allow proper grain growth and nanostructuring. In a further embodiment of the present disclosure, the thermoelectric layer is covered by depositing a high power factor electrode. Thereafter, a metal layer is deposited over the high power factor electrode. The metal layer is geometrically shaped to maximize the heat rejection. For example, a constricted metal layer comprises hemispherical contact surfaces are deposited over the high power factor electrode.

### BRIEF DESCRIPTION OF THE DRAWINGS

FIG. 1 is a schematic cross sectional view of a thermoelement, in accordance with an embodiment of the present disclosure;

FIG. 2 is a schematic diagram illustrating a cross-section of a conventional thermoelement and variation of thermal conductivity, Seebeck coefficient and temperature across the cross-section of the conventional thermoelement;

FIG. 3 is a schematic diagram illustrating a cross-section of another conventional thermoelement and variation of thermal conductivity, Seebeck coefficient and temperature across the cross-section of the conventional thermoelement;

FIG. 4 is a schematic diagram illustrating a cross-section of yet another conventional thermoelement and variation of thermal conductivity, Seebeck coefficient and temperature across the cross-section of the conventional thermoelement;

FIG. 5 is a schematic diagram illustrating a cross-section of a thermoelement in accordance with an embodiment of the present disclosure, and variation of thermal conductivity, Seebeck coefficient and temperature across the cross-section of the thermoelement;

FIG. 6 illustrates a graph depicting variation of a phonon conductivity criterion and effective Lorenz number with the atomic number;

FIG. 7 is a flowchart illustrating a method of manufacturing a thermoelement, in accordance with an embodiment of the present disclosure;

FIG. 8 is an image illustrating a top surface of a thermoelement in accordance with an embodiment of the present disclosure; and

FIG. 9 illustrates a thermoelement in accordance with an embodiment of the present disclosure.

### DETAILED DESCRIPTION OF THE DISCLOSURE

Before describing the embodiments in detail in accordance with the present disclosure, it should be observed that these embodiments reside primarily in the apparatus for thermoelectric cooling and power generation and the method for manufacturing it. Accordingly, the method steps and the system components have been represented to show only those specific details that are pertinent for an understanding of the embodiments of the present disclosure, and not the details that will be apparent to those with ordinary skill in the art.

Definitions to be highlighted before describing the present disclosure in detail are:

Definition of Chalcogenides: Chalcogenides are compounds of a combination of one of the elements of group 16 elements of the periodic table and an electropositive element.

List of Acronyms used in the present disclosure:

PVD: Physical Vapor Deposition;

CVD: Chemical Vapor Deposition; and

TE films: Thermoelectric films.

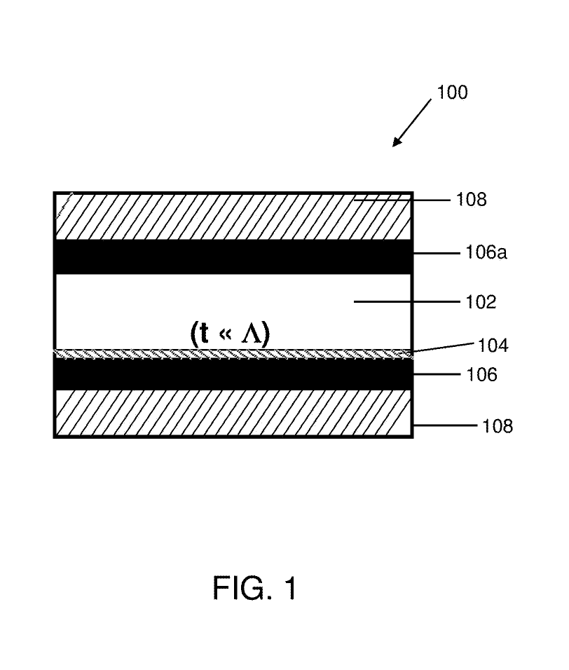

FIG. 1 is a schematic cross sectional view of a thermoelement 100, in accordance with an embodiment of the present disclosure.

In an embodiment of the present disclosure, thermoelement 100 is a NEAT device that is used in cooling and power generation applications. Thermoelement 100 includes multiple layers to perform different functions. Thermoelement 100 comprises a thermoelectric layer 102, a phonon blocking layer 104, high power factor electrodes 106 and 106a, and a plurality of metal layers 108.

The phonon blocking layer 104 includes a first side (not numbered in the figure) and a second side (not numbered in the figure). The first side of the phonon blocking layer 104 is attached to a first side (not numbered in the figure) of thermoelectric layer 102. The second side (not numbered in the figure) of phonon blocking layer 104 is attached to one of the high power factor electrodes 106. The second side (not numbered in the figure) of the thermoelectric layer 102 is attached to another high power factor electrode 106a on the top side. In other words, the phonon blocking layer 104 is positioned between thermoelectric layer 102 and high power factor electrode 106. However the layer 104 is positioned only on the first side of the thermoelectric layer 102. In an embodiment of the disclosure, the phonon blocking layer 104 may be present in any order among the various layers of the thermoelement. The electrical contact between thermoelectric layer 102 and high power factor electrodes 106 is established mainly by electronic tunneling across the interface of phonon blocking layer 104. Further, the plurality of metal layers 108 made of high conductivity materials are deposited on the high power factor electrodes 106 and 106a on both the first and the second side of the thermoelectric layer 102.

In an embodiment of the present disclosure, thermoelement 100 is used in cooling applications in an operating temperature range of about −50° C. to 100° C. In an embodiment of the present disclosure, thermoelectric layer 102 is made of at least one of materials such as Bi_{0.5}Sb_{1.5}Te₃, Bi₂Te₃, Bi₂Te_{2.7}Se_{0.3} and InSb. Thermoelement 100 as described may find application in, but not limited to, refrigeration, air-conditioning, battery cooling and distillation applications.

In an embodiment of the present disclosure, thermoelement 100 is used in power generation applications at an operating temperature range of about 100° C. to about 500° C. Thermoelectric layer 102 of thermoelement 100 may be made of at least one of materials such as Zn—Sb and Pb₁₈AgSbTe₂₀ (LAST—Lead, Argentum, Stibium and Tellurium). Thermoelement 100 as described may find usage in energy recovery applications such as generating electricity from automobile exhausts, diesel generators, fuel cell exhausts and power plant steam.

In yet another embodiment of the present disclosure, thermoelement 100 is used in power generation applications such as in gas turbine exhaust, concentrated solar applications and hybrid solar applications with the operating temperature range of about 400° C. to 800° C.

In an embodiment of the present disclosure, thermoelectric layer 102 has a thickness (t) less than a characteristic thermalization length (Λ) of the semiconductor material. The thickness (t) of the thermoelectric layer 102 is in the range of 500-1500 nanometers. For example, under certain conditions such as when thermoelectric layer 102 is made of BiTe₃, thermalization length is approximately equal to 500 nm. Another example is when thermoelectric layer 102 is made of InSb, in which case thermalization length is approximately equal to 1500 nm. Further, during usage of thermoelement 100 when the thickness of thermoelectric layer 102 is less than the thermalization length (Λ), electron transport and phonon transport may get decoupled and a state of non-equilibrium may be achieved. When the decoupled phonons are specifically impeded by phonon-blocking layer 104, the thermal conductivity of the thermoelement is decreased, and results in increase of figure of merit (as per equation (1)).

In an embodiment of the present disclosure, phonon blocking layer 104 has a thickness approximately equal to 1 nanometer. Thermal conduction across thermoelement 100 is caused by transport of phonons and electrons. High magnitude of thermal transport across thermoelement 100 can result in high thermal conductivity, reducing the figure of merit (as per equation (1)). To reduce thermal conductivity and increase figure of merit, transportation of phonons is disrupted using phonon blocking layer 104.

In another embodiment of the present disclosure, phonon blocking layer 104 is made of one or more atomic layers of graphene. Atomic layers of graphene are deposited on high power factor electrodes 106 by a CVD method. Further, graphene has a high anisotropic thermal conductivity with high thermal conductivity in the in-plane direction and very low thermal conductivity in the cross-plane direction. The introduction of a few atomic layers of graphene in the transport path can block the phonon transmission in the cross-plane direction because of the weak bonding between the carbon atoms and the disparate semiconductor molecules of Bi₂Te₃ and InSb. The highly anisotropic conductivity of the graphene layers suggest that the phonon energy from the cross-plane mode may be further dispersed into phonons in the in-plane direction and transmission to high power factor electrodes 106 will be poor. On the other hand, electrons can easily tunnel across the well regulated, few atomic layers of graphene at low fields without significant decrease in electronic conductivity. Thus, electronic conductivity of thermoelement 100 remains unaffected because of the atomic layers of graphene.

In yet another embodiment of the present disclosure, liquid metals such as nanolayers of Ga—In—Sn liquid metal alloys, are used in phonon blocking layer 104. Lack of crystal structure in the liquid metals and a large mean distance between adjacent molecules are some of the reasons for using liquid metals in phonon blocking layer 104. Moreover, electron conductivity of the liquid metals is very high (of the order of 5 S/μm) and phonon conductivity at the melting point is very low, making them suitable for use in phonon blocking layer 104. The liquid metals may be deposited in the thermoelement 100 using methods such as PVD.

In yet another embodiment of the present disclosure, tunneling oxides are used in phonon blocking layer 104. One or two atomic layers of tunneling oxides such as Aluminum Oxide (Al₂O₃) are deposited using an Atomic Layer Deposition (ALD) method. In another exemplary embodiment, refractory oxides such as Tungsten Oxide, Vanadium Oxide, and Niobium Oxide are used in phonon blocking layer 104. Refractory oxides are deposited using an Atomic Layer Deposition (ALD) method that ensures deposition of a few atomic layers.

In an embodiment of the present disclosure, the thermoelement may also include a plurality of high power factor electrodes 106. The thickness of high power factor electrodes 106 is in a range of 5 nanometers to 10 nanometers. High power factor electrodes 106 are made of a material with high Seebeck coefficient. In an embodiment of the present disclosure, materials used in high power factor electrodes 106 are YbAl₃ (Ytterbium-Aluminum) with n-type thermoelectric materials or CePd₃ (Cerium-Palladium) with p-type thermoelectric materials. These materials have a Seebeck coefficient (S_{HPF}) approximately equal to 130 μV/K. For instance, the electronic power factor (σS²) is 0.018 WK⁻² m⁻¹ for YbAl₃ and 0.01 WK⁻² m⁻¹ for CePd₃. Further, YbAl₃ and CePd₃ also have high thermal conductivity (for example ˜15 Wm⁻¹K⁻¹) and electrical conductivity (for example ˜2 S/μm) as compared to those of conventional thermoelectric materials.

In another embodiment of the present disclosure, thermoelectric materials such as crystalline Indium Antimonide and CoSb₃ are used in high power factor electrodes 106. These materials have a good Seebeck coefficient and good electrical conductivity but very poor thermal conductivity.

In thermoelement 100, heat is released or absorbed at regions where the thermopower (Seebeck coefficient) changes, particularly where the gradient of the thermopower is significant. As high power factor electrodes 106 are positioned between thermoelectric layer 102 and metal layers 108, the gradient of thermopower in thermolement 100 at the junction is reduced by more than 50% compared to conventional thermoelements. Hence, presence of high power factor electrodes 106 between thermoelectric layer 102 and the plurality of metal layers 108 reduces losses at interfaces between layers (not labeled in the figure). The high power factor electrodes are configured to reduce losses in the thermoelement while the metal layers are configured to provide contacts of the thermoelement so as to reduce the heat flux across the thermoelement.

Further, in thermoelement 100, the figure of merit of thermoelement 100 is a deciding factor of Coefficient of Performance of a thermoelectric device that uses thermoelement 100.

The equations describing heat transfer between electrons and phonons within thermoelement 100 are:

$$\begin{matrix}P ( {T}_{e} - {T}_{p} ) - ∇ \cdot ( {λ}_{3} ∇ {T}_{e} ) - \frac{{J}^{2}}{σ} = 0 & ( 2 ) \\ P ( {T}_{p} - {T}_{e} ) - ∇ \cdot ( {λ}_{p} ∇ {T}_{p} ) = 0 & ( 3 )\end{matrix}$$

Where,
P is intensity of interaction between electron and phonon;
J is local current density;
Tₑ is temperature of an electron;
Tₚ is temperature of a phonon;
σ is electrical conductivity;
λₑ is electronic thermal conductivity; and
λₚ is lattice thermal conductivity;

After solving one-dimensional coupled equations with a condition of zero phonon-based heat conduction at the interface of phonon blocking layer 104, the following expression for characteristic thermalization length, Λ is obtained:

$$Λ = \sqrt{\frac{{λ}_{e} {λ}_{p}}{[ ( {λ}_{e} + {λ}_{p} ) P ]}} \qquad ( 4 )$$

The non-equilibrium effects between electrons and photons in thermoelement 100 result in a reduction in thermal conductivity across thermoelement 100, denoted as λ_{NEAT} which is given by:

$${λ}_{NEAT} = \frac{{λ}_{e} ( {λ}_{e} + {λ}_{p} )}{{λ}_{e} + {λ}_{p} \frac{tanh ( t / Λ )}{t / Λ}} \qquad ( 5 )$$

where, t is the thickness of thermoelement 100.

When the transport length, i.e. the thickness t, is larger than the thermalization length, t/Λ→∞, λ_{NEAT}→λₑ+λₚ as expected in the conventional thermoelements.

On the other hand, when t/Λ→0, λ_{NEAT}→λₑ.

In an embodiment of the present disclosure, the thermalization length (Λ) is approximately equal to 500 nm for thermoelectric layer 102 made of Bi—Sb—Te and approximately equal to 1.4 μm for thermoelectric layer 102 made of In—Sb.

For example, when the thickness of thermoelement 100 is 400 nm, thermoelement 100 will operate in a phonon-glass-electron-crystal (PGEC) limit at the limiting value for the figure of merit as given by the following equation:

ZT=(S²Tσ)/λ->S²σT/λₑ=S²/L₀ₜ (6)

where, L₀ₜ is the Lorenz number and S is the Seebeck coefficient or the thermopower for thermoelectric layer 102.

For example, when thermoelectric layer 102 comprises Bi_{0.5}Sb_{1.5}Te₃, \sqrt{L₀ₜ} is approximately equal to 125 μV/K. Also, for Seebeck coefficient of 270 μV/K, the figure of merit (ZT) exceeds 4.

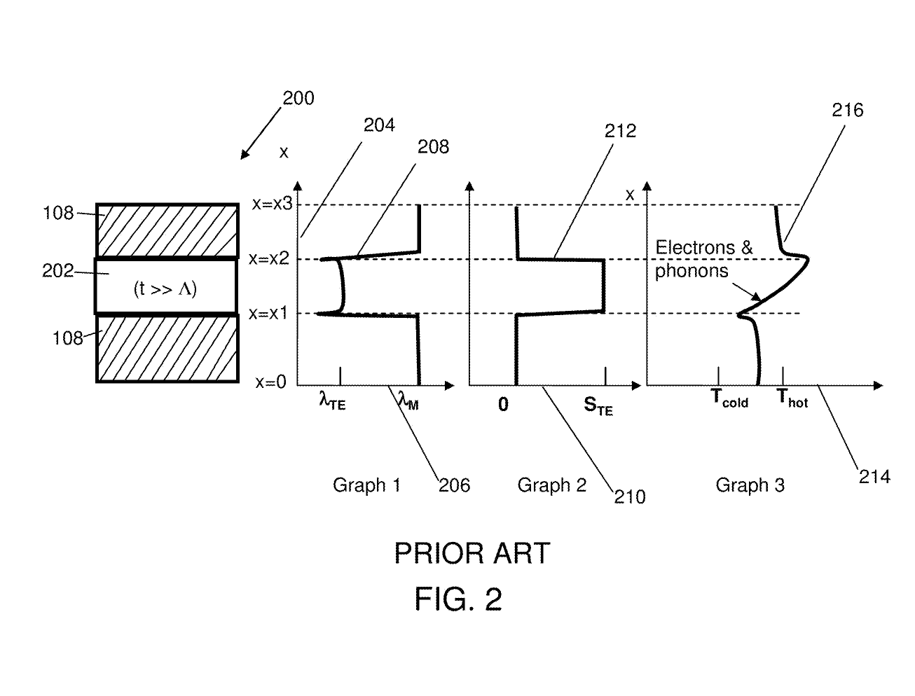

In a conventional thin film thermoelectric device 200 (described in detail in FIG. 2), half of Joule heat developed in thermoelectric layer 202 flows back to a cold side of the conventional thin film thermoelectric devices. In thermoelement 100, the backflow of Joule heat is reduced by a factor ξ.

The factor ξ is given by:

$$ξ = \frac{{λ}_{e} + {λ}_{p} [ \frac{1 - sech ( t / Λ )}{{( t / Λ )}^{2}} ]}{{λ}_{e} + {λ}_{p} \frac{tanh ( t / Λ )}{t / Λ}} \qquad ( 7 )$$

The factor ξ¦1 as t/Λ →∞, and as t/Λ→0. Reduction of backflow of Joule heat when using thermoelement 100 in the thermoelectric devices allows higher efficiency of operation at larger temperature differentials.

Further, the maximum coefficient of performance (COP) η, i.e. the ratio of the cooling power at the cold end to the total electrical power consumed by the thermoelectric device, is given by the following equation:

$$η = ( \frac{{T}_{c}}{{T}_{h} - {T}_{c}} ) \cdot [ \frac{\sqrt{1 + {S}^{2} / {L}_{0}} - 1}{\sqrt{1 + {S}^{2} / {L}_{0}} + 1} ] \qquad ( 8 )$$

For example, when thermoelement 100 is used in typical air-conditioning applications with a temperature differential of 25K (45° F.) and room temperature approximately equal to 300K, COP exceeds 5!

FIG. 2 is a schematic diagram illustrating a cross-section of a conventional thermoelement 200 and variation of thermal conductivity, Seebeck coefficient and temperature across the lateral dimension.

Conventional thermoelement 200 comprises a conventional thermoelectric layer 202 between two metal layers 108. As marked in FIG. 2, the thickness of conventional thermoelectric layer 202 is greater than the thermalization length (Λ). Therefore, electrons and phonons, which are responsible for thermal conduction across interfaces of conventional thermoelement 200, are in equilibrium.

Graph 1 depicts variation of thermal conductivity across various points of conventional thermoelement 200. Axis 204 (marked as x-axis) is a vertical axis representing the corresponding points along the transverse (vertical) dimension of conventional thermoelement 200. X=0 represents a first end of conventional thermoelement 200. X=X1 represents an interface between metal layer 108 and thermoelectric layer 202. X=X2 represents an interface between top metal layer 108 and thermoelectric layer 202. X=X3 represents a second end of thermoelement 200.

Axis 206 is a horizontal axis representing thermal conductivity. A curve 208 represents variation of thermal conductivity across various points of the cross-section of conventional thermoelement 200. As depicted in FIG. 2, the thermal conductivity is high at metal layers 108 and low at conventional thermoelectric layer 202. Further, the thermal conductivity decreases abruptly at interfaces (at X=X1 and X=X2) between metal layers 108 and conventional thermoelectric layer 202.

Graph 2 depicts variation of Seebeck coefficient across layers of conventional thermoelement 200. Axis 210 is a horizontal axis representing the Seebeck coefficient. A curve 212 represents variation of Seebeck coefficient across the cross-section of conventional thermoelement 200. As depicted in FIG. 2, Seebeck coefficient is approximately equal to zero inside metal layers 108 and is constant (equal to S_{TE}) inside thermoelectric layer 202. There are abrupt changes in Seebeck coefficient at interfaces (X=X1 and X=X2) of thermoelement 200.

Graph 3 depicts variation of temperature across layers of conventional thermoelement 200. Axis 214 is a horizontal axis representing the temperature. Curve 216 represents variation of temperature across the cross-section of conventional thermoelement 200. X=X3 represents a hot end of thermoelement 200 and X=0 represents a cold end of thermoelement 200.

As depicted in curve 216, electrons and phonons are in thermal equilibrium across the thermoelectric layer 202. Thermal equilibrium between electrons and phonons implies that thermal conductivity is simply the sum of thermal conductivity due to phonons (λₚ) and thermal conductivity (λₑ) due to electrons. The net thermal conductivity across the thermoelement 200 is high which results in reduction of the figure of merit of the thermoelectric device. (Refer to equation (1))

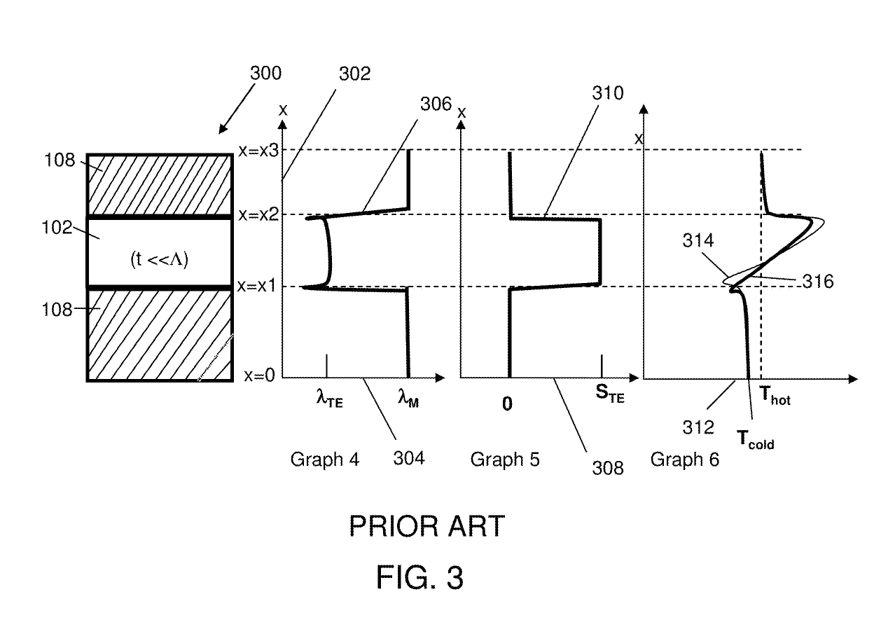

FIG. 3 is a schematic diagram illustrating a cross-section of a conventional thermoelement 300 and variation of thermal conductivity, Seebeck coefficient and temperature across the cross-section. It is to be noted that as an exemplary illustration, conventional thermoelement 300 is a thin film thermoelement.

Conventional thermoelement 300 comprises thermoelectric layer 102 between two metal layers 108. As marked in FIG. 3, the thickness of conventional thermoelectric layer 102 is less than the thermalization length (Λ). Therefore, electrons and phonons are not in thermal equilibrium inside the thermoelectric layer 102.

Graph 4 depicts variation of thermal conductivity across layers of thin film thermoelement 300. Axis 302 is a vertical axis representing points along the transverse (vertical) dimension of conventional thermoelement 300. X=0 represents a first end of conventional thermoelement 300. X=X1 represents an interface between one of metal layers 108 and thermoelectric layer 102. X=X2 represents an interface between the other metal layer 108 and thermoelectric layer 102. X=X3 represents a second end of conventional thermoelement 300.

Further, axis 304 is a horizontal axis representing thermal conductivity. Curve 306 represents the variation of thermal conductivity across the cross-section of conventional thermoelement 300. As depicted in FIG. 3, the thermal conductivity is high at metal layers 108 and low at thermoelectric layer 102. Further, the thermal conductivity decreases abruptly at the interfaces between metal layers 108 and thermoelectric layer 102.

Graph 5 depicts variation of Seebeck coefficient across layers of conventional thermoelement 300. Axis 308 is a horizontal axis representing the Seebeck coefficient. Curve 310 represents variation of Seebeck coefficient across the cross-section of conventional thermoelement 300. As depicted in FIG. 3, Seebeck coefficient is approximately equal to zero at metal layers 108 and remains constant (equal to S_{TE}) at thermoelectric layer 102. Further, at interfaces (X=X1 and X=X2), abrupt decrement of Seebeck coefficient is observed.

Graph 6 depicts variation of temperature across layers of conventional thermoelement 300. Axis 312 is a horizontal axis representing the temperature. X=X3 represents a hot end of conventional thermoelement 300 and X=0 represents a cold end of conventional thermoelement 300. Curve 314 represents variation of temperature across the cross-section of conventional thermoelement 300 caused by electrons. Curve 316 represents variation of temperature across the cross-section of conventional thermoelement 300 caused by phonons. However, when phonons and electrons are not in thermal equilibrium, the temperature across the phonon and electron systems inside the thermoelectric layer 102 is determined by the temperature of metal layers 108 at the hot end that is thermally coupled to the ambient reservoir. The thermal conductivity of thermoelectric layer 102 is the sum of thermal conductivity due to phonons (λₚ) and thermal conductivity (λₑ) due to electrons. The net thermal conductivity across thermoelement 300 is high, which again results in reduction of the figure of merit of the thermoelectric device (as per equation (1)).

Further, curves 314 and 316 also illustrate that there is a large temperature drop and rise at the interfaces X=X1 and X=X2 respectively. These temperature drops and rise occur within thermoelectric layer 102, and the net temperature differential across metal layers 108 of the thermoelement 300 is small.

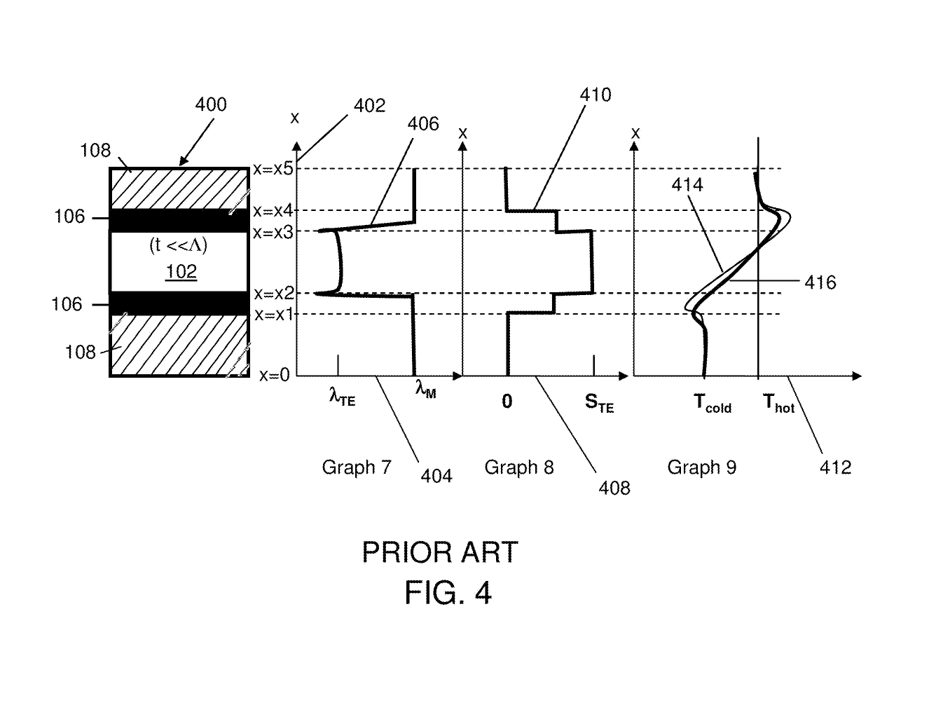

FIG. 4 is a schematic diagram illustrating a cross-section of a conventional thermoelement 400 and variation of thermal conductivity, Seebeck coefficient and temperature across the cross-section.

Thermoelement 400 comprises thermoelectric layer 102, metal layers 108, and high power factor electrodes 106 (thermoelectric layer 102, metal layers 108, and high power factor electrodes 106 are described in conjunction with FIG. 1). As marked in FIG. 4, the thickness of thermoelectric layer 102 is less than the thermalization length (Λ). Therefore, a state of electrons and phonons are not in thermal equilibrium.

Graph 7 depicts variation of thermal conductivity across layers of thermoelement 400. Axis 402 is a vertical axis representing corresponding points along the transverse (vertical) dimension of thermoelement 400. X=0 represents a first end of thermoelement 400. X=X1 represents a first interface between metal layer 108 and high power factor electrode 106. X=X2 represents a second interface between high power factor electrode 106 and thermoelectric layer 102. X=X3 represents a third interface between thermoelectric layer 102 and the top high power factor electrode 106. X=X4 represents a fourth interface between high power factor electrode 106 and metal layer 108. X=X5 represents a second end of thermoelement 400.

Axis 404 is a horizontal axis representing thermal conductivity. Curve 406 represents variation of thermal conductivity across various points of thermoelement 400. As depicted in FIG. 4, the thermal conductivity is high at metal layers 108 and high power factor electrodes 106 and low at thermoelectric layer 102. Further, at X=X2, the thermal conductivity reaches a minimum and then increases. The thermal conductivity decreases abruptly at the interface between high power factor electrode layers 106 and thermoelectric layer 102 at X=X3. However, there are no large changes in the thermal conductivity at the interfaces X=X1 and X=X4 between high power factor electrode layer 106 and the metal layers 108. The thermal conductivity remains approximately constant between X=0 and X=X2 at the cold end and X=X3 and X=X5 at the hot end

Graph 8 depicts variation of Seebeck coefficient across layers of thermoelement 400. Axis 408 is a horizontal axis representing the Seebeck coefficient. Curve 410 represents variation of Seebeck coefficient across various points of thermoelement 400. As depicted in FIG. 4, between X=0 and X=X1, the Seebeck coefficient is about zero inside metal layer 108. Between X=X1 and X=X2, a step gradient is observed at high power factor electrode 106. Between X=X2 and X=X3, the Seebeck coefficient is almost constant (equal to S_{TE}, as denoted in the figure) inside thermoelectric layer 102. A drop in the Seebeck coefficient to an intermediate value corresponding to the Seebeck coefficient of the high power factor electrodes is observed at X=X3. The Seebeck coefficient drops to a minimum value (about zero) at X=X4 and is constant at metal layer 108. High power electrodes 106 significantly reduce the gradient of the Seebeck coefficient at the interfaces X=X2 and X=X3 (by at least a factor of approximately two).

Graph 9 plots variation of temperature across layers of thermoelement 400. Axis 412 is a horizontal axis representing the temperature. X=X5 represents a hot end of thermoelement 400 and X=0 represents a cold end. Curve 414 represents variation of temperature across various points of thermoelement 400 due to electrons. Curve 416 represents variation of temperature across various points of thermoelement 400 due to phonons. The electrons and phonons are not in thermal equilibrium inside the thermoelectric layer 102 because the thickness of the thermoelectric layer 102 is smaller than the thermalization length (Λ). Even though the phonon and electron systems are not in thermal equilibrium, the temperature across the phonon and electron systems inside the thermoelectric layer 102 are determined by the temperature of the high power factor electrodes 106 and the metal layers 108 at the hot end that is thermally coupled to the ambient reservoir. The thermal conductivity of the thin film thermoelectric layer 102 is still the sum of thermal conductivity due to phonons (λₚ) and thermal conductivity due to electrons (λₑ). The net thermal conductivity across the thermoelement 400 is high, which again results in reduction of the figure of merit of the thermoelectric device.

However, in contrast with the case depicted in FIG. 3, the curves 414 and 416 illustrate that there is a large temperature drop and rise at the interfaces X=X2 and X=X3 respectively. The temperature drop and rise at the interfaces result from smaller gradients of Seebeck coefficient at the interfaces X=X2 and X=X3 and high thermal conductivity of the high power factor electrodes. Hence, the net temperature differential across the metal layers 108 of the thermoelement 400 is significantly enhanced.

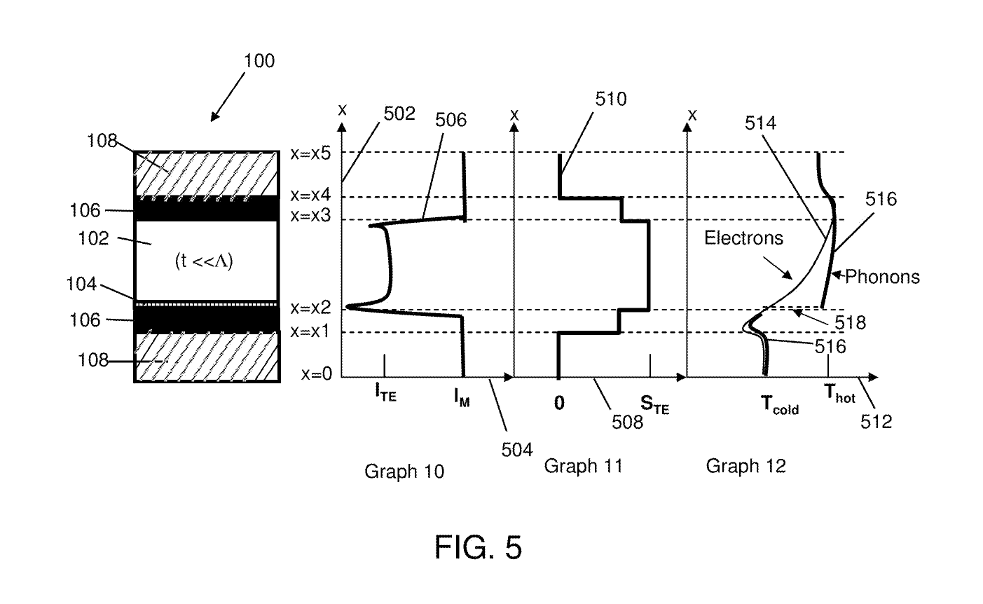

FIG. 5 is a schematic diagram illustrating a cross-section of thermoelement 100 in accordance with an embodiment of the present disclosure, and variation of thermal conductivity, Seebeck coefficient and temperature across the cross-section of thermoelement 100. In an embodiment of the present disclosure, thermoelement 100 is a Non-Equilibrium Asymmetric Thermoelectric (NEAT) device.

Thermoelement 100 has been described in detail in conjunction with FIG. 1. Thermoelement 100 comprises thermoelectric layer 102, phonon blocking layer 104, high power factor electrodes 106, and metal layers 108. As marked in FIG. 5, the thickness of thermoelectric layer 102 is less than the thermalization length (Λ). Therefore, electrons and phonons are not in thermal equilibrium.

Graph 10 depicts variation of thermal conductivity across various points of thermoelement 100. Axis 502 is a vertical axis representing points along the transverse (vertical) dimension of thermoelement 100. X=0 represents a first end of thermoelement 100, X=X1 represents an interface between metal layer 108 and high power factor electrodes 106, X=X2 represents an interface between phonon blocking layer 104 and layer 102, X=X3 represents the interface between thermoelectric layer 102 and high power factor electrode 106, X=X4 represents the interface between high power factor electrodes 106 and metal layer 108 and X=X5 represents a second end of thermoelement 100.

Axis 504 is a horizontal axis representing thermal conductivity. Curve 506 represents variation of thermal conductivity across various points of thermoelement 100. As depicted in FIG. 5, from X=0 to X=X2 and from X=X3 to X=X5 (inside metal layers 108 and high power factor electrodes 106), the thermal conductivity is mostly high. The thermal conductivity decreases significantly at the interfaces between high power factor electrodes 106 and thermoelectric layer 102, and reaches a minimum at phonon blocking layer 104 (at X=X2). The phonon thermal conductivity remains approximately constant inside most of thermoelectric layer 102.

Graph 11 depicts variation of Seebeck coefficient across layers of thermoelement 100. Axis 508 is a horizontal axis representing the Seebeck coefficient. Curve 510 represents variation of Seebeck coefficient across the cross-section of thermoelement 100. As depicted in FIG. 5, Seebeck coefficient is approximately equal to zero inside metal layers 108 and is constant (equal to S_{TE}) inside thermoelectric layer 102. Further, inside high power factor electrodes 106, the Seebeck coefficient has an intermediate value in the range: 0.4S_{TE}-S_{TE}

Graph 12 plots variation of temperature across layers of thermoelement 100. Axis 512 is a horizontal axis representing the temperature. X=X5 represents a hot end of thermoelement 100 and X=0 represents a cold end of thermoelement 100. Graph 12 depicts variation of temperature caused by electrons and phonons when energy transfer takes place in thermoelement 100. Curve 514 represents variation of temperature across the cross-section of thermoelement 100 due to transport of electrons. Curve 516 represents variation of temperature across the cross-section of thermoelement 100 due to transport of phonons. The electrons and phonons are not in thermal equilibrium inside the thermoelectric layer 102 because the thickness of the thermoelectric layer 102 is smaller than the thermalization length (Λ). However, in contrast with the prior art devices depicted in FIG. 3 and FIG. 4, the phonon-blocking layer 104 selectively blocks the transport of phonons without impeding the electron transport. An arrow 518 represents the effect of phonon blocking, i.e. the large discontinuous temperature drop for the phonon system in thermoelement 100. The thermal conductivity of thermoelectric layer 102 is equal to thermal conductivity (λₑ) due to electrons. The blocking of phonons results in significantly enhanced non-equilibrium effect and reduction of thermal conductivity. (Please refer to FIG. 5 between X=X2 and X=X3). As high power factor electrodes 106 reduce the temperature losses at interfaces, the figure of merit of thermoelement 100 is significantly improved.

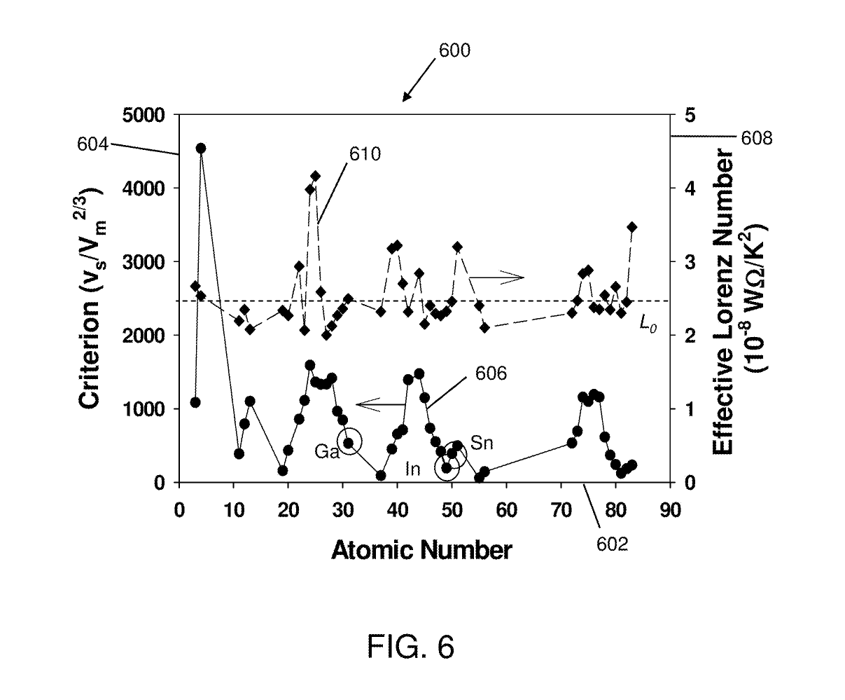

FIG. 6 illustrates a graph 600 depicting variation of a phonon conductivity criterion for metals and effective Lorenz number with the atomic number of elements.

Graph 600 is analyzed to identify elements that can be used as good phonon blocking layers. Liquid metals have properties making them suitable for use in the phonon blocking layers. For instance, electron conductivity of the liquid metals is high (of the order of 5 S/λm). The phonon conductivity of the elements at the melting point is proportional to a phonon conductivity criterion (V_{S}/Vₘ^{2/3}), where:

V_{S} is the velocity of sound; and

Vₘ is the molar volume.

In FIG. 6, axis 602 is a horizontal axis representing atomic numbers of the elements. Axis 604 is a vertical axis representing the phonon conductivity criterion, which is used for assessing the thermal phonon conductivities of the elements at their melting point. A curve 606 represents variation of the phonon conductivity criterion (and therefore variation of the thermal phonon conductivities) of the elements with their atomic numbers. As seen from FIG. 6, Gallium (atomic number 31), Indium (atomic number 49), and Tin (atomic number 50) have some of the lowest thermal phonon conductivities at their melting points (even in their elemental form).

Axis 608 is a vertical axis representing effective Lorenz number (10⁻⁸ WΩ/K²). At a given temperature, Lorenz number represents the ratio of electronic contribution towards the thermal conductivity to that of the product of absolute temperature and electrical conductivity of a metal. A curve 610 illustrates variation of Lorenz number of the elements with the atomic number.

Nanolayers of Ga—In—Sn liquid metals have attributes of a good phonon blocking layer because of a lack of defined crystal structure and large mean distance between adjacent molecules that results in very poor ionic thermal conductivity. As evident from FIG. 6, these elements have among the lowest thermal phonon conductivities as well as low Lorenz number. Hence, in an embodiment of the present disclosure, nanolayers of Ga—In—Sn liquid metals have been used as phonon blocking layer 104. Further, in an embodiment of the present disclosure, the lowest melting point composition, Ga₆₈In₂₀Sn₁₂ has been used as phonon blocking layer 104.

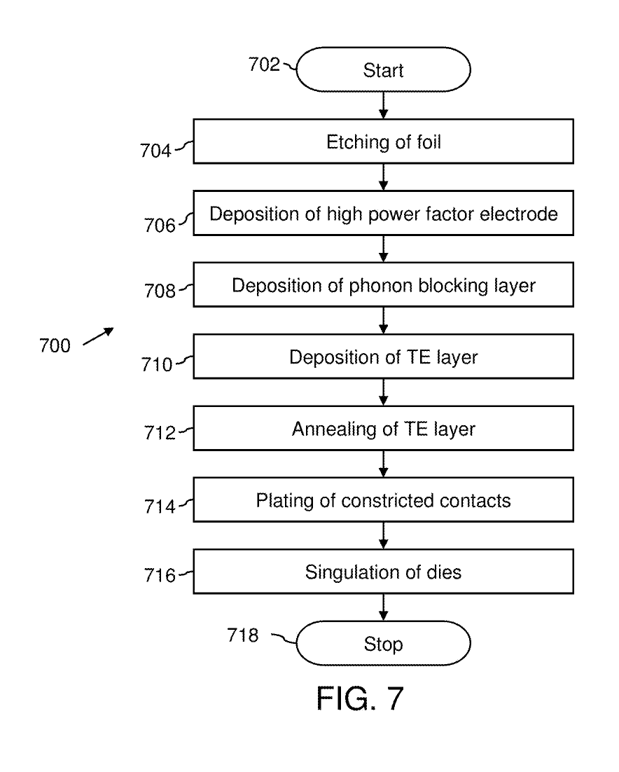

FIG. 7 is a flowchart 700 illustrating a method of manufacturing thermoelement 100, in accordance with an embodiment of the present disclosure.

The method starts at 702. In an embodiment of the present disclosure, a Mo (Molybdenum) foil of about 25 μm thickness is used as a metal layer. At step 704, the Mo foil may be chemically etched. For example, chemical etching of Mo foil may be wet etching with acids (e.g. mixture of HNO₃, H₃PO₄ and CH₃COOH) or by dry etching using XeF₂ to form hemispherical indents on the Mo foil surface. At step 706, a high power factor electrode is deposited on the metal layer. In an embodiment of the present disclosure, materials such as YbAl₃ for an n-type thermoelectric layer and CePd₃ for a p-type thermoelectric layer are used in the high power factor electrode. For example, the deposition of the high power factor electrode on metal layers is carried out by a method such as sputtering or PVD. In another embodiment of the present disclosure, thermoelectric materials such as indium antimonide, and CoSb₃ are used in high power factor electrodes. These materials have a good Seebeck coefficient and good electrical conductivity but high thermal conductivity.

At step 708, a phonon blocking layer is deposited on the high power factor electrode by a technique such as CVD. In an embodiment of the present disclosure, atomic layers of graphene are deposited as the phonon blocking layer. Further, the deposited atomic layers of graphene are analyzed by methods such as Transmission Electron Microscopy (TEM) and Raman Spectroscopy to confirm that the layers of graphene are only a few atoms thick. In another embodiment of the present disclosure, liquid metals are deposited as the phonon blocking layer. Deposition of liquid metals such as Ga, In, and Sn can be carried out by sputtering (or PVD process).

In yet another embodiment of the present disclosure, tunneling oxides are used in phonon blocking layer. One or two monolayers of tunneling oxides such as Aluminum Oxide (Al₂O₃) are deposited using an Atomic Layer Deposition (ALD) method. In yet another embodiment of the present disclosure, refractory oxides such as Tungsten Oxide, Vanadium Oxide, and Niobium Oxide are used in the phonon blocking layer. Refractory oxides may be deposited using an Atomic Layer Deposition (ALD) method that ensures deposition of a few monolayers only.

At step 710, a thermoelectric layer is deposited on the phonon blocking layer through a process such as PVD. In an embodiment of the present disclosure, one or more thermoelectric materials such as Bi_{0.5}Sb_{1.5}Te₃, Bi₂Te₃, and InSb are used in thermoelectric layer 100. At step 712, the thermoelectric layer is heat treated to allow proper grain growth. In an embodiment, the heat treatment performed on the thermoelectric layer includes annealing and quenching that allows proper nanostructure to be established in the thermoelectric layer.

In an embodiment, according to step 714, the thermoelectric layer is protected with diffusion barriers that prevent diffusion of metals such as copper and gold comprising metal layers. In an embodiment of the present disclosure, metal layers structures are fabricated to form constricted contacts through plating techniques and resulting in hemispherical contact surfaces.

At step 716, singulation of thermoelements is performed by etching the molybdenum foil. Further, in an exemplary embodiment, dicing may be performed to obtain thermoelements of desired dimensions.

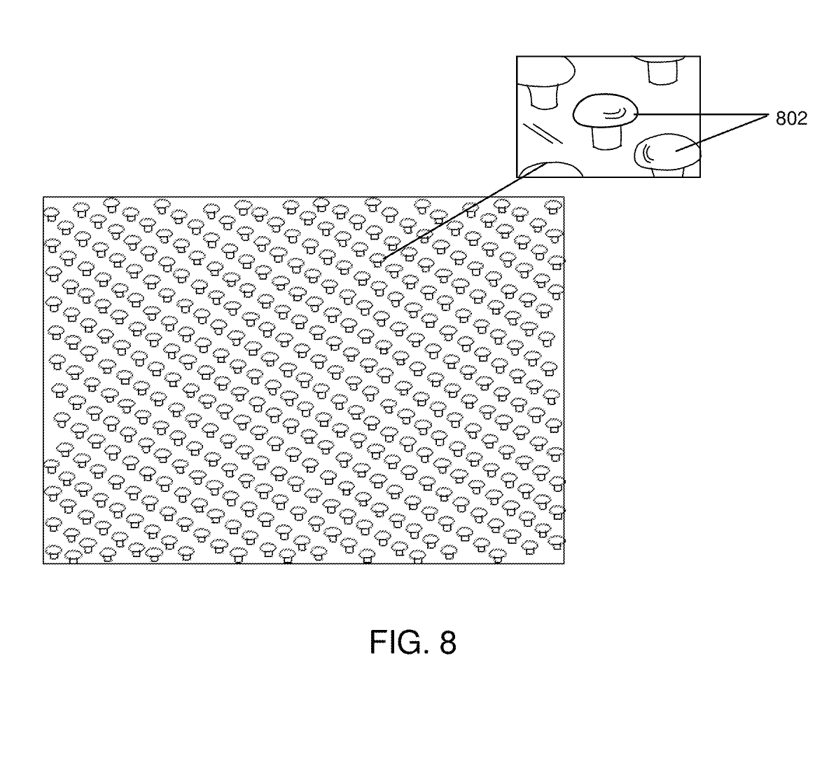

FIG. 8 is an image illustrating a top surface 800 of a thermoelement (not shown in the figure) in accordance with an embodiment of the present disclosure. For illustrative purpose, top surface 800 may be an equivalent to metal layers 108 at the top of thermoelement 100, as explained in conjunction with FIG. 1.

As depicted in FIG. 8, top surface 800 comprises a plurality of metal contacts 802. The plurality of metal contacts may be referred as a plurality of micro thermoelements, wherein the plurality of micro thermoelements combine together to form the thermoelement. In an embodiment of the present disclosure, metal contacts 802 are constricted metal structures. For example, metal contacts 802 can have hemispherical surface at contact areas for efficient heat spreading across the thermoelement.

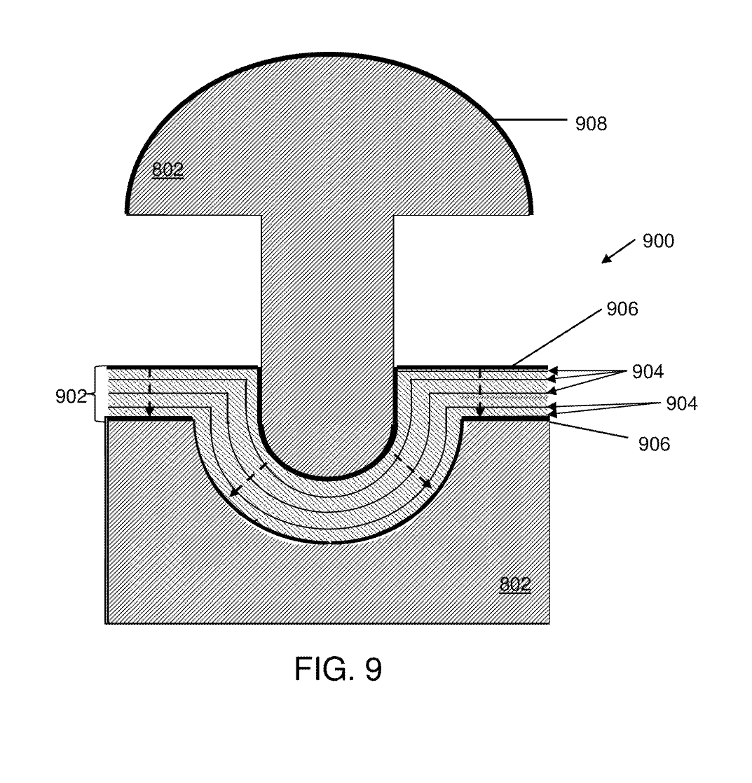

FIG. 9 illustrates a cross sectional view of a thermoelement 900 in accordance with an embodiment of the present disclosure.

Thermoelement 900 comprises a graded thermoelectric layer 902 comprising multiple graded layers separated by phonon blocking layers 904, high power factor electrodes 906, metal contacts 802, and a top metal layer 908.

In accordance with an embodiment of the present disclosure, graded thermoelectric layer 902 comprises layers made of different thermoelectric materials and the layers are separated by phonon blocking layers 904 (as shown in FIG. 9).

For example, graded thermoelectric layer 902 may comprise four layers separated by phonon blocking layers 904, starting from bismuth telluride at a cold end (the cold end refers to mushroom shaped contact structure 802 at the top) of thermoelement 902, followed by a lead tellurium alloy layer, then a layer of an alloy of lead tellurium and silver antimony telluride alloy and then a layer of a silver antimony telluride alloy. The purpose of having graded thermoelectric layers 902 as mentioned in the example is to maximize the Seebeck coefficient (thermopower) over a wide temperature range. In the example, bismuth telluride may have an optimal thermopower within a temperature range of approximately 50° C.-150° C., lead tellurium alloy has better thermopower within the temperature range of 150° C. to 200° C., lead tellurium and silver antimony telluride alloy has an optimal thermopower at approximately 250° C., and silver antimony telluride at approximately 400° C.

In an embodiment of the present disclosure surfaces of graded thermoelectric layer 902 are covered with high power factor electrodes 906. (Properties of high power factor electrodes are explained in detail in conjunction with FIG. 1). High power factor electrodes 906 are in turn covered with metal contacts 802. In an embodiment of the present disclosure, metal contacts 802 may be constricted contacts having hemispherical geometry at one surface (cold end) of the thermoelement 900 and flat at the other surface (hot end). For example, metal contacts 802 can be made of one of the materials such as copper, nickel, molybdenum, and tungsten or the like. Further, the top surface of hemispherical metal contact 802 is covered with top metal layer 908. In an embodiment, top metal layer 908 is made of gold to enable easy soldering or bonding. Furthermore, it should be understood that the hemispherical geometry of metal contacts 802 provides efficient heat transfer. However, other types of geometry for metal contacts 802 are also possible as will be understood by the person skilled in the art.

The thermoelements and the thermoelectric devices described in various embodiments of the present disclosure provide high efficiency energy conversion. The thermoelement described in various embodiments of the present disclosure can be used in cooling applications, power generation applications and energy recovery applications.

The present disclosure provides thermoelements that have low manufacturing cost and can be manufactured in high volume (manufacturing thermoelements in high volume and then dicing them into individual units as per requirement). Also, unlike magnetocaloric and electrocaloric methods, the thermoelements in combination with thermoelectric devices described in the present disclosure do not involve moving components or special hardware to isolate phase change mass from hot and cold sides.

It should be noted that applications of the device or the thermoelements described herein, in accordance with the various embodiments of the present disclosure, should not be taken as limitations. The thermoelement device could find applications that are not mentioned or described in the present disclosure that are known to the person skilled in the art.

While the preferred embodiments of the invention have been illustrated and described, it will be clear that the invention is not limited to these embodiments only. Numerous modifications, changes, variations, substitutions, and equivalents will be apparent to those skilled in the art without departing from the spirit and scope of the invention.

What is claimed is:

1. A thermoelement for use in a thermoelectric device, the thermoelement comprising:
a thermoelectric layer having a thickness less than a thermalization length, the thermoelectric layer having a first side and a second side;
a phonon blocking layer having a first side and a second side, the first side of the phonon blocking layer coupled to the first side of the thermoelectric layer, the phonon blocking layer being configured to block phonon conduction and permit electron transport across the thermoelement;
a first high power factor electrode and a second high power factor electrode, wherein the first high power factor electrode is coupled to the second side of the phonon blocking layer and the second high power factor electrode is coupled to a second side of the thermoelectric layer, the first high power factor electrode and the second high power factor electrode being configured to reduce thermal losses in the thermoelement; and
a plurality of metal layers coupled to the first high power factor electrode and the second high power factor electrode, the plurality of metal layers being configured to reduce the heat flux across the thermoelement.

2. The thermoelement of claim 1, wherein the phonon blocking layer is present in any order among the thermoelectric layer, the first and the second high power factor electrode and the plurality of metal layers in the thermoelement.

3. The thermoelement of claim 1, wherein the metal layer is geometrically shaped to provide maximum heat rejection.

4. The thermoelement of claim 3, wherein the metal layer is geometrically shaped as a hemispherical shell with concave section and a convex section.

5. The thermoelement of claim 1 comprising a plurality of micro thermoelements, wherein the plurality of micro thermoelements combine together to form the thermoelement.

6. The thermoelement of claim 1, wherein the phonon blocking layer comprises one or more atomic layers of graphene.

7. The thermoelement of claim 1, wherein the phonon blocking layer comprises one or more atomic layer of liquid metals selected from a group consisting of Gallium, Indium, Tin, Lead and Bismuth.

8. The thermoelement of claim 1, wherein the phonon blocking layer comprises one or more atomic layers of refractory metals selected from a group consisting of Titanium, Tungsten, Molybdenum, and Tantalum.

9. The thermoelement of claim 1, wherein the phonon blocking layer comprises one or more atomic layers of noble metals selected from a group consisting of Silver, Gold and Platinum.

10. The thermoelement of claim 1, wherein the phonon blocking layer comprises one or more atomic layers of metal oxides selected from a group consisting of Aluminum oxide, Hafnium oxide, Titanium oxide, Niobium oxide and Tantalum oxide.

11. The thermoelement of claim 1, wherein the thickness of the thermoelectric layer is less than the thermalization length of 1500 nm.

12. The thermoelement of claim 1, wherein the thermoelectric layer comprises at least two or more layers separated by the phonon blocking layers.

13. A thermoelement for use in a thermoelectric device comprising:
one or more thermoelectric layers having a thickness less than a thermalization length;
one or more phonon blocking layers in contact with the one or more thermoelectric layers, wherein the one or more phonon blocking layers are configured to block phonon conduction across the thermoelement;
a plurality of high power factor electrodes in contact with the one or more of the phonon blocking layers, wherein the plurality of high power factor electrodes are configured to reduce thermal losses in the thermoelement; and
a plurality of metal layers coupled to the plurality of high power factor electrodes, the plurality of metal layers being configured for providing constricted contacts of the thermoelement to reduce the heat flux across the thermoelement.

14. A method of manufacturing a thermoelement for use in a thermoelectric device, the method comprising:
depositing a first high power factor electrode on a metal layer, the first high power factor electrode being configured to reduce temperature losses in the thermoelement;
depositing a phonon blocking layer on the first high power factor electrode, the phonon blocking layer being configured to block phonon conduction across the thermoelement;
depositing a thermoelectric layer on the phonon blocking layer;
depositing a second high power factor electrode on the thermoelectric layer, the second high power factor electrode being configured to reduce losses in the thermoelement; and
depositing a metal layer on the second high power factor electrode.

15. The method of claim 14 further comprising the step of heat treatment of the thermoelectric layer to allow proper gain growth.

16. The method of claim 14, wherein the plurality of metal layers is fabricated in a geometric shape to provide the maximum heat rejection.
